(19) United States
(12) Patent Application Publication
(10) Pub. No.: US 2014/0008012 A1
(43) Pub. Date: Jan. 9, 2014

(54) METHOD FOR PRODUCING MORE PARTICULARLY PROCESSING OR POPULATING, A CIRCUIT BOARD ELEMENT AND CARRIER FOR USE IN SUCH A METHOD

(71) Applicants: Gerhard Freydl, Leoben-Hinterberg (AT); Markus Leitgeb, Trofaiach (AT)

(72) Inventors: Gerhard Freydl, Leoben-Hinterberg (AT); Markus Leitgeb, Trofaiach (AT)

(21) Appl. No.: 14/006,741

(22) PCT Filed: Mar. 26, 2012
(86) PCT No.: PCT/AT12/00078

§ 371 Date: Sep. 23, 2013

(30) Foreign Application Priority Data
Mar. 29, 2011 (AT) GM 177/2011

(51) Int. Cl. H05K 3/00

(52) U.S. Cl. CPC H05K 3/007
USPC 156/247; 156/538

(57) ABSTRACT

In a method for producing a circuit board element, the following steps are provided:
providing a substantially whole-area carrier having an adhesive surface;
arranging and fixing a starting material of the circuit board element to be produced on the adhesive surface of the carrier;
producing the circuit board element fixed on the carrier in a position fixed on the carrier; and
removing the produced circuit board element from the carrier.

Furthermore, a carrier for use in such a method is provided, wherein it is possible, in particular, to dispense with complex steps for separating or singulating circuit board elements and, with conservation of resources as a result of reusability of a carrier, it is possible to obtain cost savings in the production of circuit board elements.

This is a national stage of PCT/AT2012/000078 filed Mar. 26, 2012 and published in German, which has a priority of Austria no. GM 177/2011, filed Mar. 29, 2011, hereby incorporated by reference.

### FIELD OF THE INVENTION

The present invention relates to a method for producing, in particular processing or loading a circuit board element, comprising the steps of
providing a substantially full-area carrier having an adhering surface;
disposing and fixing on said adhering surface of the carrier a starting material of the circuit board element to be produced, in particular processed or loaded;
producing, in particular processing or loading, the circuit board element fixed to the carrier in a position fixed on the carrier; and
removing the produced, in particular processed or loaded, circuit board element from the carrier.

The invention relates furthermore to a carrier for usage in such a method, wherein the carrier is formed with an adhering surface for fixing at least one circuit board element or starting material for the same.

### PRIOR ART

In the context of the production of circuit board elements or circuit boards, it is known to produce a plurality of circuit boards or circuit board elements on or in a common plate-shaped element, such circuit boards, as a rule, each comprising a plurality of conducting and insulating layers and/or components integrated in such a circuit board, and/or being loaded or populated with components. According to those known production methods, the substantially whole-area or full-area mounting of a plurality of circuit boards on or in the common plate-shaped element is effected, whereupon, after completion of the circuit boards, the latter are separated from one another. In those cases, each of the circuit boards has a respective edge region about its periphery, and hence outside a substantially central region forming an actual circuit board element, in which central region the structures for mounting the circuit board and/or the electronic components are integrated. Said edge region is, for instance, provided for carrying out further circuit board processing steps such as, for instance, in the context of the insertion of components to be fixed to at least one surface and/or the installation into an electric or electronic device, in order to enable the manipulation and, in particular, automatic seizure of such a circuit board during subsequent treatment or processing steps. According to presently known process controls, it is thus to be anticipated that the peripheral region to be provided for the frame or peripheral region of the circuit board is likewise produced of a usually expensive material in correspondence with the usually multi-layered circuit board. Such an edge or peripheral region, which is not required for the functioning of the circuit board, will however, result in elevated costs of such a circuit board, bearing in mind the usually multilayer assembly of expensive materials. In the context of known production methods of circuit boards, it is, moreover, to be anticipated that regions or areas located between individual circuit board elements, of the common plate-shaped element are discarded as waste products such that elevated costs for the production of circuit boards or circuit board elements will also occur in this respect.

In connection with the production of circuit boards it is, moreover, known to remove individual defective circuit boards from a common plate-shaped element if they have been recognized as defective in the course of tests or checks, and to replace such removed, defective circuit boards with individual, proper circuit boards.

A method and a carrier of the type mentioned-above are known from US 2006/0112543 A1, for example, wherein it is aimed at a reduction or elimination of errors when producing or populating or loading circuit boards.

From JP 4 342196 A there has become known a method, wherein an improved positioning of an element should be achieved when populating a circuit board by providing a special marker.

According to JP 2006 135041 A it is aimed at a particular and safe fixation of a component when populating a circuit board.

In addition, methods for collectively processing or treating and handling circuit boards or circuit board elements of the initially defined kind are known, according to which several circuit boards or circuit board elements are usually inserted into carrier or frame elements each surrounding the circuit boards about their entire peripheries, and fixed to them, for instance by gluing, so as to produce a composite structure comprised of at least one frame or carrier element and a plurality of circuit boards. In this respect, it is, for instance, referred to DE-A 1906 00 928, U.S. Pat. No. 4,689,103 or U.S. Pat. No. 5,044,615. Those known methods for inserting circuit boards into a frame element each completely surrounding the circuit boards in order to produce a composite structure to be jointly handled, in particular, involve the drawbacks that the reception openings to be provided in the frame element for the arrangement of the circuit boards have to be precisely adapted to the dimensions of the circuit boards to be inserted, and a proper fixation, for instance by gluing to the peripheral edges of the circuit boards and frame elements, which usually have comparatively small thicknesses, is therefore extremely difficult and cumbersome.

In the context of the production of circuit board elements or circuit boards, it is, furthermore, known to connect such circuit board elements with frame or carrier elements surrounding such circuit board elements or circuit boards only over a partial region of their peripheries in order to at least partially overcome the above-described drawbacks of overall fitting. In this context, it is, for instance, referred to WO 2010/102315.

The known methods, moreover, involve the disadvantages that, in particular, when adapting the dimensions of the circuit boards and/or circuit board elements to be inserted and subsequently treated or processed, also the dimensions of the frame or carrier elements are accordingly differently selected such that in subsequent processing operations, for instance in insertion or loading lines, an exchange of the circuit boards to be treated or processed will require accordingly much time for the conversion of such processing lines to adapt the same to different dimensions of, in particular, the composite structures formed by the at least one frame or carrier element and the plurality of circuit boards.

All of the known methods using frame or carrier elements involve the disadvantage of requiring additional material for such frame or carrier elements, which will be disposed of after having completed the circuit board elements or circuit boards, thus leading to additional costs for the production and, in particular, processing or loading of such circuit board elements. In addition, the isolation of the circuit board elements or circuit boards after their production or completion by separation from the employed frame or carrier elements will involve accordingly high expenditures.

### SUMMARY OF THE INVENTION

The present invention aims to further develop a method and a carrier for carrying out said method, of the initially defined kind in the context of the production and, in particular, processing or loading or populating of circuit board elements or circuit boards to the effect that the above-mentioned drawbacks of the prior art will be avoided and a method and carrier will, in particular, be provided, which will enable the use of additional material for frame or carrier elements to be minimized or largely eliminated, and additional working steps for separating the produced or finished circuit board elements from such frame or carrier elements to be obviated, or their execution to be strongly simplified.

To solve these objects, a method for producing, in particular processing or loading or populating, a circuit board element according to the type mentioned above is essentially characterized in that a circuit board element configured with a surface deviating from a flat surface is disposed on the carrier in a recess or depression having a profile complementary to the surface contour of the circuit board element.

While, during the production or processing of a circuit board element, such circuit board element usually have substantially planar or full-area structures in an early production or processing state so as to enable the simple and reliable fixation to a likewise full-area or plane carrier provided with an adhering surface, it is partially known, or to be anticipated, in particular in further production or processing steps, that, for instance, in the formation of different layers or plies, or the arrangement or at least partial integration of components in or on such a circuit board elements, contours or subregions deviating from a plane surface, of such a circuit board element are provided or to be expected. For reliably and properly fixing such a circuit board element, it is proposed according to the invention that a circuit board element configured with a surface deviating from a flat surface is disposed on the carrier in a recess or depression having a profile complementary to the surface contour of the circuit board element. By such a mode of operation, not only the desired precise positioning of the circuit board element on the carrier will be enabled, but it will also be possible to take into account the design deviating from a plane surface contour, of a circuit board element to be arranged or fixed, by shaping the carrier accordingly.

By the proposed steps, it has become possible to substantially completely renounce the use of at least one frame or carrier element to be connected to a circuit board element to be produced, in particular processed or loaded or populated, and at least partially adapted to the contours of such a circuit board element, since it is proposed to provide a substantially whole-area or full-area carrier having an adhering surface, to which a circuit board element, or the starting material for the same, can be temporarily fixed via the adhering surface for production steps to be performed. The production and, in particular, processing or loading of such a circuit board element will be effected in a state fixed to, or disposed on, the carrier, on its adhering surface, whereupon, after having completed or terminated the processing or loading steps, the circuit board element will be readily removed from the adhering surface of the carrier element and subjected to a further treatment or processing operation.

It is immediately apparent that, as opposed to the known prior art, the use of frame or carrier elements to be at least partially adapted to the contours of a circuit board element to be processed can be fully renounced such that the material input can be accordingly reduced or minimized in the production of a circuit board element or circuit board, since, unlike in the known prior art, no such frame or carrying elements need be disposed of, which would increase the overall production costs. Such a full-area carrier having an adhering surface can thus be used in a simple and reliable manner for a plurality of circuit board element production and processing operations while accordingly reducing or minimizing the costs for the production of such circuit board elements. Such a reduced material input for the carrier or frame element, besides reduced costs, will also ensure the appropriate conservation of resources, and hence the environment.

The method according to the invention, moreover, enables the provision of a uniform carrier format that is readily adapted to production and processing plants substantially independently of a circuit board element to be processed or produced, so that cumbersome conversions to fit possibly different formats of circuit board element or circuit board production or processing plants can be obviated.

By the method according to the invention it has, moreover, become possible to optionally process individual circuit board elements in such production or processing plants, so that, as opposed to the prior art, no accordingly large-area formats on which a plurality of mostly identical circuit board elements are usually disposed need be subjected to such processing or production operations. The method according to the invention thus enables the customized production of circuit board elements or, for instance, prototypes for test periods, such customized or single-unit productions again enabling an accordingly reduced material input, particularly in circuit board or circuit board element development stages.

By providing a carrier having an adhering surface for fixing a circuit board element, the method according to the invention moreover, for instance, enables different circuit board elements to be subjected to a joint production or processing operation, since the desired arrangement and fixation of such optionally different circuit board elements on such a common carrier will be enabled in a simple and reliable manner according to demands.

By arranging and fixing an individual circuit board element each on the carrier, accordingly precise positioning and orienting will also be feasible, since, as opposed to the known prior art, no orientation of large-area formats usually containing a plurality of circuit board elements is effected in a production or processing operation, wherein, for instance, tolerances in the mutual arrangement of such a plurality of circuit board elements in a specific format may cause respective inaccuracies in the actual positioning of individual circuit board elements in a format. By the arrangement and fixation or positioning proposed according to the invention, of each individual circuit board element, such inaccuracies in respect to the relative positioning of such a plurality of circuit board elements will be avoided. In doing so, the fixation of a circuit board element with an accuracy or precision of better than ±30 μm and, in particular, down to ±10 μm will be achieved. This will, for instance, enable the precise localization and, for instance, reliable bonding of accordingly small-structured elements in a circuit board element.

In addition, the method according to the invention, by simply removing a circuit board element after the production or processing operation, allows for the simplification of the method steps to the effect that expensive isolation or separation steps of individual circuit board elements from frame or carrier elements can be obviated.

For the particularly reliable and exact positioning of individual circuit board elements or circuit boards on the carrier formed with an adhering surface, it is proposed according to a preferred embodiment of the method according to the invention that the circuit board element is disposed on the adhering surface of the carrier by referring to at least two marks, in particular registration marks, provided in or on the circuit board element. By providing marks or registrations marks on each circuit board element, the reliable and precise positioning of each circuit board element on the carrier for the subsequent processing or completion of such a circuit board element will thus be enabled same irrespectively of any possible positioning of further circuit board elements on said carrier, as already briefly mentioned above.

For producing or processing a circuit board element, it is proposed according to a further preferred embodiment that, during producing, in particular processing or loading, the circuit board element together with the carrier is subjected to a treatment under elevated pressure and/or elevated temperature relative to ambient conditions. In doing so, such production or treatment steps under elevated pressure and/or elevated temperature relative to ambient conditions are known per se in the context of producing or processing circuit board elements or circuit boards.

In a position fixed or located on a carrier formed with an adhering surface, a plurality of different production or processing steps can be performed on such a circuit board element, wherein, in this connection, it is proposed according to a further preferred embodiment of the method according to the invention that, during producing, in particular processing or loading, the circuit board element, mounting or forming at least one further layer or ply of the circuit board element, structuring at least one layer or ply of the circuit board element, fixing and/or inserting at least one active or passive component on or in the circuit board element is/are performed. It is thus immediately apparent that, during a substantially provisional or temporary positioning or fixation of a circuit board element, substantially all of the production or processing operations known in connection with the production of such circuit board elements can be preformed on a circuit board element or circuit board.

In the context of the method according to the invention, a plurality of different circuit board elements or circuit boards can be subjected to manufacturing and, in particular, processing or loading operations, wherein, in this connection, it is proposed according to a further preferred configuration that the circuit board element is comprised of a rigid, flexible or rigid-flexible circuit board element, a circuit board intermediate product or semi-finished product, or a rigid, flexible or rigid-flexible circuit board.

As already indicated above, the use of the method according to the invention not only provides the facility to produce or process individual circuit board elements, but also enables a plurality of, optionally different, circuit board elements to be subjected to a treatment while, in particular, optimizing the exploitation of the space available on such a carrier, wherein, in this connection, it is proposed according to a further preferred embodiment of the method according to the invention that a plurality of circuit board elements are disposed and/or fixed on the carrier and subjected to a joint production operation, in particular processing or loading operation.

In addition to the processing of optionally a plurality of circuit board elements by arrangement or fixation on a common carrier, it is, moreover, proposed that at least two circuit board elements that are arranged next to each other on the carrier are connected to each other during producing, in particular processing or loading, as in correspondence with a further preferred embodiment of the method according to the invention. It is thus possible to not only allow for a particularly reliable and, by avoiding frame or carrier elements that will subsequently have to be disposed of, cost-effective production or processing of circuit board elements, but also enable the coupling or connecting of, optionally different, circuit board elements, or circuit board elements having different structures, in a simple and reliable manner by appropriate arrangement on a common carrier in an appropriate spatially close relationship during such production or processing operations in order to produce a suitable circuit board element or circuit board. By being disposed on such a common carrier, rigid and flexible portions of a circuit board may thus, for instance, be coupled or connected in a simple and reliable manner while observing accordingly precise relative positions.

To solve the initially mentioned objects, a carrier according to the type mentioned above for performing the method according to the invention is, moreover, provided, which is essentially characterized in that the surface of the carrier for the arrangement of a circuit board element is formed with a profile that is complementary to a circuit board external surface deviating from a flat surface. By providing a reusable carrier having an adhering surface, the simple and reliable fixation of at least one circuit board element or starting material for the same will be ensured in order to enable the reliable production, in particular processing or loading, of such a circuit board element. For the reliable positioning and accommodation of circuit board elements or circuit boards having contours deviating from a plane surface contour, for instance due to the already effected insertion of electronic components and/or mounting of different layers or plies, it is proposed according to the invention that the surface of the carrier for the arrangement of a circuit board element is formed with a profile that is complementary to a circuit board external surface deviating from a flat surface.

For the production or processing of circuit board elements or circuit boards, elevated pressure and/or temperature conditions relative to ambient conditions are frequently applied, as already pointed out above, wherein, in addition to the materials used for such circuit board elements, also the carrier material will have to be dimensionally stable and resistant to elevated pressure and/or temperature conditions in order to maintain the desired precise positions of the same. In this connection, it is proposed according to a preferred embodiment of the carrier that the material for the carrier is selected from metals such as aluminum, steel or the like, or from dimensionally stable and high-temperature-resistant, in particular fiber-reinforced, synthetic materials such as duroplasts or thermoplasts like, e.g., polyarylenes, polyarylene ether, polyarylene ether ketones, polyarylates, polyarylene sulfides, polyarylene ether sulfones, polyarylene amides, polyimides.

Besides an appropriate resistance and dimensional stability of the carrier material, also the material used for the adhering surface is to be able to withstand the pressure and/or temperature conditions encountered during the production or processing of circuit boards or circuit board elements, wherein, in this connection, it is proposed according to a further preferred embodiment that the adhering surface of the carrier is formed by dimensionally stable and high-temperature-resistant synthetic materials such as, e.g., polymerized adhesive low-molecular silicone resins such as, in particular, cross-linked polymethyl siloxanes or polymethylphenyl siloxanes, etc.

### SHORT DESCRIPTION OF THE DRAWINGS

In the following, the invention will be explained in more detail by way of exemplary embodiments schematically illustrated in the annexed drawing. Therein:

FIG. 1 illustrates a first embodiment of a carrier according to the invention for carrying out the method of the invention, including a plurality of circuit board elements disposed or fixed thereon, wherein FIG. 1a depicts a top view in the sense of arrow IA of FIG. 1b, and FIG. 1b depicts a sectional view along line IB-IB;

FIG. 2, in an illustration similar to that of FIG. 1, depicts a modified embodiment of a carrier according to the invention for carrying out the method of the invention,

FIG. 2a again depicting a top view, and FIG. 2b again depicting a section similar to the illustration according to FIG. 1;

FIG. 3 is a detailed view on an enlarged scale, wherein the mounting of a further layer or ply, or the insertion of an electronic component, in a circuit board element disposed or fixed on a carrier is indicated;

FIG. 4 in an illustration similar to that of FIG. 3 depicts a modified embodiment, with the connection or coupling of different circuit board elements in positions disposed on the carrier being indicated; and

FIG. 5 schematically illustrates a process diagram depicting individual method steps of the method according to the invention.

### DETAILED DESCRIPTION OF PREFERRED EMBODIMENTS

In the context of the present description, starting materials for a circuit board element to be produced and/or processed are partially also referred to as circuit board elements, since these are mainly semi-finished or intermediate products which, according to the usual nomenclature, are denoted as circuit board elements both before and after processing.

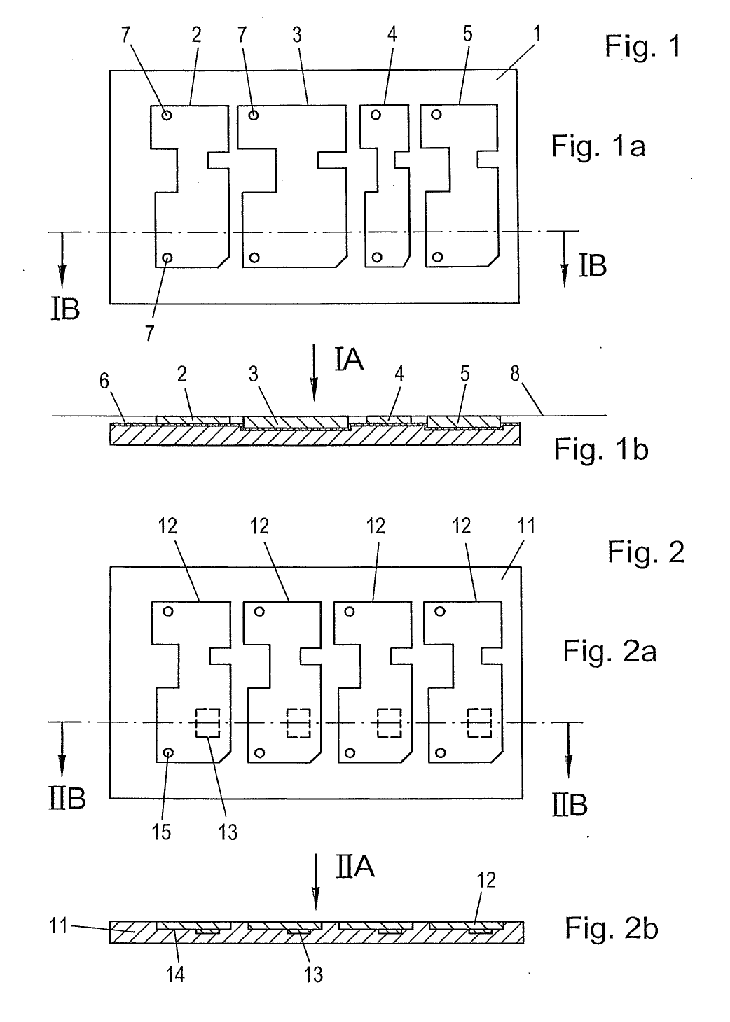

From the illustration according to FIG. 1, it is apparent that, on a substantially whole-area or full-area carrier generally denoted by 1, a plurality of circuit board elements 2, 3, 4, 5, or starting materials for the same, are disposed and fixed to the carrier 1 via an adhesion layer schematically indicated by 6. In FIG. 1, it is schematically indicated that the circuit board elements 2 to 5 have different sizes and dimensions, with the utilization of space being, in particular, optimized.

To ensure reliable and precise positioning, it is, moreover, apparent, in particular from FIG. 1a, that the circuit board elements 2 to 5 each have marks, in particular registration marks 7, to enable the precise and reliable positioning of the circuit board elements 2 to 5 on the carrier 1 independently of further circuit board elements optionally already disposed on, or fixed to, the carrier 1.

In order to achieve a common treating or processing height, which is schematically indicated by line 8 in FIG. 1b, it is, moreover, apparent from this illustration that elements 3 and 5 are disposed in subregions of the carrier 1 that are accordingly offset taking into account the different thickness of the individual circuit board elements.

After having finished or completed the production and/or processing operations, as will be discussed below by way of the additional Figures, the circuit board elements 2 to 5 can again be removed from the surface of the carrier 1 in a simple and reliable manner such that cumbersome isolation or separation steps for removing frame or carrier elements connected to individual circuit board elements can be renounced.

The carrier 1 can subsequently be used for further treatment or processing operations of further circuit board elements such that, consequently, not only the material consumption for the production of circuit board elements or circuit boards 2 to 5 will be reduced, but, due to the reduced material input, also a corresponding conservation of resources and the environment will be enabled.

From the illustration according to FIG. 2, it is apparent that a plurality of circuit board elements 12 or starting materials, which are in this case identical, are disposed on a carrier denoted by 11. The circuit board elements 12, for instance, each comprise an integrated electronic component 13, from which a surface contour deviating from a plane surface, of the individual circuit board elements 12 results, as is, in particular, apparent from the illustration according to FIG. 2b. For the proper arrangement and fixation of the circuit board elements 12, it is thus provided for the carrier 11 that it is formed with a surface accordingly contoured in conformity with the surface contour of the circuit board elements 12 provided with the components 13, such profiled or offset subregions of the carrier being indicated by 14.

The precise positioning and orientation of the individual circuit board elements 12 is again performed using the marks or registration marks indicated by 15.

For the sake of simplicity, the illustration of an adhering surface or adhesive layer has been omitted from FIG. 2 and, in particular, FIG. 2b.

Like in the embodiment according to FIG. 1, the simple removal or extraction of the individual circuit board elements 12 from the carrier 11 can be performed after having finished or completed the producing or processing operation, so that the advantages already mentioned several times in respect to the avoidance of cumbersome separation or isolation steps as well as the saving of material and the conservation of resources will again be achievable.

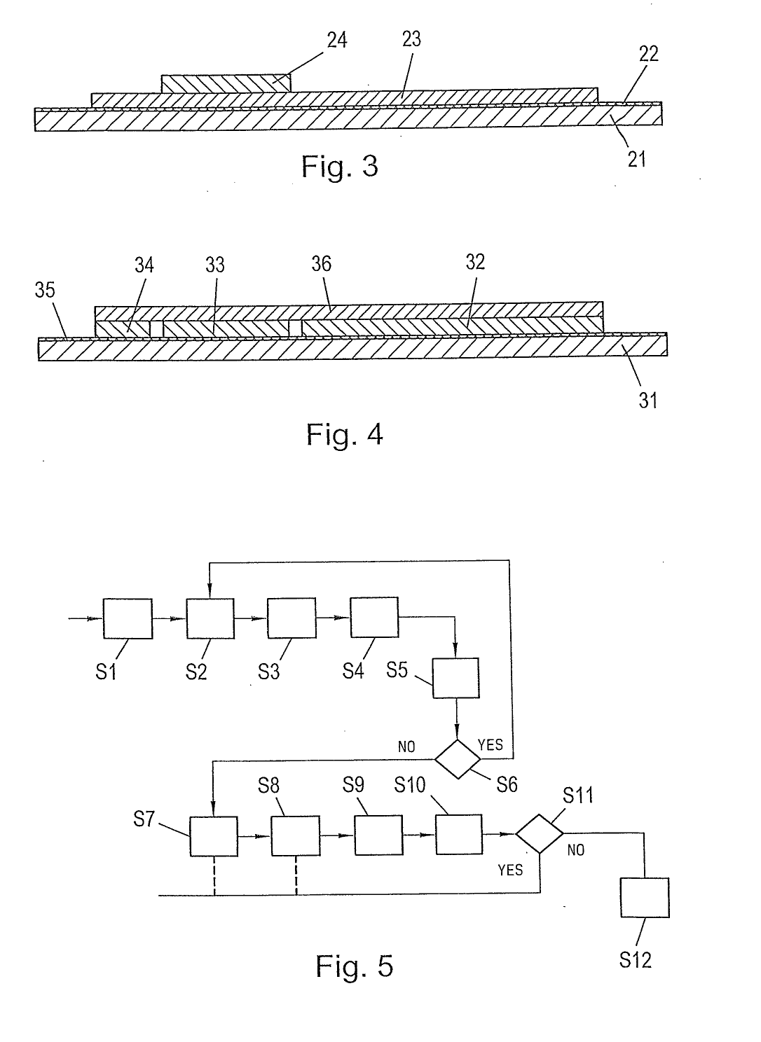

In the illustration according to FIG. 3, it is indicated how the appropriate treatment and/or processing operations are performed in the respective treating or processing steps following the positioning and/or fixation of individual circuit board elements on a carrier. In FIG. 3, a carrier is denoted by 21, with the fixation of a circuit board element 23 being effected via an adhesive layer or adhering surface indicated by 22. In the context of a producing or processing operation to be performed after the fixation and/or positioning, a further layer or ply 24 is disposed on the circuit board element 23 in the embodiment according to FIG. 3, this being feasible by steps known per se in the production of circuit boards or circuit board elements.

Instead of mounting an additional layer or ply 24, the insertion of an electronic component in the surface of the circuit board element 23 disposed or fixed on the surface of the carrier 21 can, for instance, be provided in the embodiment according to FIG. 3.

In the modified embodiment according to FIG. 4, it is indicated that a plurality of circuit board elements 32, 33 and 34 are disposed on a carrier 31 via an interposed adhering surface or adhesion layer 35. In the context of treating or processing said plurality of circuit board elements 32, 33 and 34, which are respectively disposed on the carrier in a spatially close relationship, connecting or coupling of the circuit board elements 32, 33 and 34 to be connected to one another, which may optionally be differently structured, is, for instance, effected by forming or mounting a further layer or ply 36.

In the schematic process diagram according to FIG. 5, it is indicated that, in step S1, an individual circuit board element or individual circuit board is each supplied from a reservoir (not illustrated) or from a preceding production and treatment process. In step S2, the circuit board element is, for instance, taken up by an automatic manipulation device, whereupon, in step S3, the orientation of the circuit board element is performed while, in particular, taking into account the marks or registration marks provided therefor, and after this, in step 4, the positioning and fixation of such an individual circuit board element on the carrier as is, for instance, illustrated in FIGS. 1 and 2 is, for instance, effected via the automatic manipulation device.

After an optionally required check of the position of the circuit board element on the carrier according to step S5, it is checked and decided, in step S6, whether further circuit board elements will be disposed and fixed on the carrier. If the decision of step S6 is YES, step 2 is resumed, and steps S2 to S5 are repeated for the arrangement and fixation of further circuit board elements on the carrier.

If the decision in step S6 is NO such that either only a single circuit board element is to be processed or treated, or no further circuit board elements are to or can be arranged on the carrier as a function of the requirements or the available space, the carrier with the at least one circuit board element disposed thereon, in step 7, is transported to a consecutively arranged production or processing station, wherein, in step S8, a solder paste is, for instance, applied, whereupon, in step S9, the application of a further layer of ply, or an electronic component to be disposed on the circuit board element, as is schematically indicated in FIGS. 3 and 4, is performed after an optionally required measurement. Following such an arrangement of an additional layer or ply, or an electronic component, according to step S9, said additional layer or electronic component is, for instance, fixed in a reflow furnace according to step 10, using production or processing methods that are known per se for the production of a circuit board element or circuit board.

In step S11, it is checked whether additional treatment or processing steps are to be performed. If the decision in step S11 is YES, steps S7 and S8 are, for instance, resumed as a function of the requirements or production or processing operations to be performed, and the production or processing steps, or modified production or processing steps, are accordingly repeated several times, which have, however, not been separately illustrated in FIG. 5 for the sake of simplicity.

If the decision in step S11 is NO, and the production or processing operation of the at least one circuit board element on the carrier has thus been terminated, the at least one processed circuit board element is subsequently simply removed from the carrier according to step 12, whereupon the carrier is again available to further production or processing operations by arranging and/or fixing at least one further circuit board element, and can, for instance, be reused in step S4.

The material of the carrier 1, 11, 21 and 31, respectively, for use in processing steps known per se for the production or processing of circuit board elements or circuit boards, is, for instance, selected from metals such as, e.g., aluminum, steel or the like, or from dimensionally stable and high-temperature-resistant, in particular fiber-rein-forced, synthetic materials such as duroplasts or thermoplasts like, e.g., polyarylenes, polyarylene ether, polyarylene ether ketones, polyarylates, polyarylene sulfides, polyarylene ether sulfones, polyarylene amides, polyimides or the like.

For the safe and reliable fixation of at least one circuit board element on the carrier during the execution of the respective processing or production operations, it is, moreover, provided that the adhesive layer 6, 22 and 35 of the carrier 1, 11, 21 and 31, respectively, is, for instance, formed by dimensionally stable and high-temperature-resistant synthetic materials such as, e.g., polymerized adhesive low-molecular silicone resins like, in particular, cross-linked polymethyl siloxanes or polymethylphenyl siloxanes, etc.

1. A method for producing, in particular processing or loading, a circuit board element, comprising the steps of
providing a substantially full-area carrier having an adhering surface;
disposing and fixing on said adhering surface of the carrier a starting material of the circuit board element to be produced, in particular processed or loaded;
producing, in particular processing or loading, the circuit board element fixed to the carrier in a position fixed on the carrier; and
removing the produced, in particular processed or loaded, circuit board element from the carrier,
wherein a circuit board element configured with a surface deviating from a flat surface is disposed on the carrier in a recess or depression having a profile complementary to the surface contour of the circuit board element.

2. The method according to claim 1, wherein the circuit board element is disposed on the adhering surface of the carrier by referring to at least two marks, in particular registration marks, provided in or on the circuit board element.

3. The method according to claim 1, wherein, during producing, in particular processing or loading, the circuit board element together with the carrier is subjected to a treatment under elevated pressure and/or elevated temperature relative to ambient conditions.

4. The method according to claim 1, wherein, during producing, in particular processing or loading, the circuit board element, mounting or forming at least one further layer or ply of the circuit board element, structuring at least one layer or ply of the circuit board element, fixing and/or inserting at least one active or passive component on or in the circuit board element is/are performed.

5. The method according to claim 1, wherein the circuit board element is comprised of a rigid, flexible or rigid-flexible circuit board element, a circuit board intermediate product or semi-finished product, or a rigid, flexible or rigid-flexible circuit board.

6. The method according to claim 1, wherein a plurality of circuit board elements are disposed and/or fixed on the carrier and subjected to a joint production operation, in particular processing or loading operation.

7. The method according to claim 1, wherein at least two circuit board elements that are arranged next to each other on the carrier are connected to each other during producing, in particular processing or loading.

8. The carrier for use in a method according to claim 1, wherein the carrier is formed with an adhering surface for fixing at least one circuit board element or starting material for the same, wherein the surface of the carrier for the arrangement of a circuit board element is formed with a profile that is complementary to a circuit board external surface deviating from a flat surface.

9. The carrier according to claim 8, wherein the material for the carrier is selected from metals such as aluminum, steel or the like, or from dimensionally stable and high-temperature-resistant, in particular fiber-reinforced, synthetic materials such as duroplasts or thermoplasts like, e.g., polyarylenes, polyarylene ether, polyarylene ether ketones, polyarylates, polyarylene sulfides, polyarylene ether sulfones, polyarylene amides, polyimides.

10. The carrier according to claim 8, wherein the adhering surface of the carrier is formed by dimensionally stable and high-temperature-resistant synthetic materials such as, e.g., polymerized adhesive low-molecular silicone resins such as, in particular, cross-linked polymethyl siloxanes or polymethylphenyl siloxanes, etc.

11. (canceled)

12. (canceled)
